(19) United States
(12) Patent Application Publication
(10) Pub. No.: US 2018/0253005 A1
(43) Pub. Date: Sep. 6, 2018

(54) TRANSPARENT PHOTOSENSITIVE RESIN

(71) Applicant: Microcosm Technology Co. Ltd, Tainan City (TW)

(72) Inventors: Tang-Chieh Huang, Tainan City (TW); Kunhan Hsieh, Tainan City (TW)

(73) Assignee: Microcosm Technology Col, Ltd.

(21) Appl. No.: 15/714,958

(22) Filed: Sep. 25, 2017

(30) Foreign Application Priority Data
Mar. 2, 2017 (TW) 106106824

(51) Int. Cl. G03F 7/038

(52) U.S. Cl. CPC G03F 7/0387

(57) ABSTRACT

A transparent photosensitive resin is provided. The transparent photosensitive resin comprises a polyimide and a filler. The polyimide has the structure of formula (1):

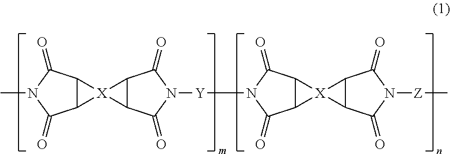

Wherein m, n are independently 1 to 600; X is a tetravalent organic group, and the main chain of X includes alicyclic structure; Y is a divalent organic group, and the main chain of Y includes siloxane structure; Z is a divalent organic group, and the side chain of Z includes phenolic hydroxyl group or carboxyl group. The filler include at least one of aluminium oxide, inorganic clay, mica powder, silicon dioxide, zinc oxide, and zirconium dioxide. The filler has an amount of weight accounting for 10-50% of total weight of the transparent photosensitive resin. The transmittance at 400-700 nm of the transparent photosensitive resin is larger than 90%. The b value of the transparent photosensitive is smaller than 2.

### BACKGROUND OF THE INVENTION

### Field of the Invention

The present invention discloses a transparent photosensitive resin, and particularly a transparent photosensitive resin containing an imidized polyimide.

### Description of the Prior Art

In general, the polyimide resin is prepared from the condensation polymerization of an aromatic tetracarboxylic acid or a derivative thereof with an aromatic diamine or an aromatic diisocyanate. The prepared polyimide resin has excellent heat resistance, chemical resistance, and mechanical and electrical properties. The aromatic photosensitive polyimides having these excellent properties are widely used in electronic materials, such as semiconductor sealants.

However, the aromatic polyimide is not suitable for use as a transparent protective layer or an insulating layer for a liquid crystal display device because the aromatic polyimide has a lower transmittance in the visible region, a color of yellow or brown, and relatively high dielectric constant. The epoxy resin or acrylic resin composition has been widely used as the transparent protective layer or insulating layer in the liquid crystal display device. However, the heat resistance of such resin is poor, which limits the subsequent process conditions to be below 230° C. When such resin is treated at a temperature of 250° C. or higher, severe discoloration and film shrinkage may occur. Therefore, in order to meet the heat resistance and transparency simultaneously, people again consider the use of polyimide materials. There have been studies on transparent polyimide films, such as Macromolecules (1994), Vol. 27, p. 1117; Vol. 26, p. 4961, and Japanese Patent Application Laid-Open No. 2001-330721, etc.

Polyimide resin can be further divided into non-photosensitive polyimide and photosensitive polyimide (PSPI). If the non-photosensitive transparent polyimide resin is used as the protective layer or insulating layer of the liquid crystal display device, a step of forming a micro-pattern by a lithographic method is further needed after the polyimide film is formed on the substrate made of glass or the like. However, non-photosensitive transparent polyimides are prone to large volume shrinkage (often up to 20-50%) during thermal curing, resulting in significant deformation of patterned features, reduced critical resolution, and induction of greater thermal stresses, which significantly limits their applications in optoelectronic devices.

### SUMMARY OF THE INVENTION

It is an object of the present invention to provide a transparent photosensitive resin having dimensional stability and transparency. The transparent photosensitive resin comprises a polyimide and a filler. The polyimide has a structure of Formula 1 below:

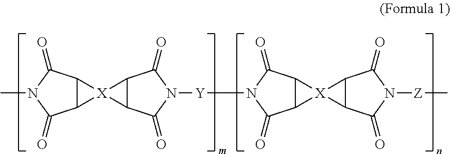

wherein m and n are each independently 1 to 600; X is a tetravalent organic group, a main chain of which contains an alicyclic compound group; Y is a divalent organic group, a main chain of which contains a siloxane group; Z is a divalent organic group, a side chain of which at least contains a phenolic hydroxyl group or a carboxyl group. The filler includes at least one of alumina, inorganic clay, mica powder, silicon oxide, aluminum oxide (Al₂O₃), zinc oxide, and zirconium oxide. The content of the filler accounts for 10-50% of the total weight of the transparent photosensitive resin. This transparent photosensitive resin has a transmittance of greater than 90% at a wavelength of 400-700 nm and b value of chromatic aberration is less than 2.

The transparent photosensitive resin described above may further be optionally added an acrylic resin photo-crosslinking agent and/or a thermal crosslinking agent.

The transparent photosensitive resin described above can be developed with an alkaline aqueous solution, and has the advantages of low curing temperature, high retention rate of film thickness, low residue rate of development, excellent flatness, easy formation of fine patterns, high sensitivity, high transmittance, and good adhesion. The transparent photosensitive resin of the present invention can provide not only a filter having excellent heat and chemical resistance and high quality, but also a transparent columnar spacer having excellent heat and chemical resistance and high quality. Moreover, it can be used as a planarization layer or a passivation film of a thin film transistor liquid crystal display (TFT-LCD), or a protective layer, an insulating layer, or a transparent printed circuit board of a touch panel.

### BRIEF DESCRIPTION OF THE DRAWINGS

FIG. 1 depicted the FT-IR spectrum of the polyimide PSPI-1 and the transparent photosensitive resin PSPI-CL1 prepared according to Example 1 of the present invention.

### DETAILED DESCRIPTION OF THE EMBODIMENTS

The present invention provides a transparent photosensitive resin, which has a main component of photosensitive polyimide having a specific molecular structure and improves the yellowness value and visible light transmittance by adding the filler, thereby making the resin transparent. The thermal crosslinking agent having a phenolic compound or an alkoxy methylation amino resin in its structure may be further added so that the terminal group on the molecular chain of the polyimide forms a crosslinking structure with the thermal crosslinking agent upon exposure and baking in order to improve the chemical resistance and film-forming property of the polyimide. The acrylic resin photo-crosslinking agent may also be added to produce the acid after exposure, thereby creating the acid-catalyzed crosslinking mechanism.

The transparent photosensitive resin of the present invention comprises: (a) a polyimide; (b) a filler having a particle size between 5 and 40 nm and comprising one or more of alumina, inorganic clay, mica powder, silicon oxide, aluminum oxide (Al₂O₃), zinc oxide, and zirconium oxide; (c) an acrylic resin photo-crosslinking agent; (d) a thermal crosslinking agent including a phenolic compound, an alkoxy methylation amino resin, or an epoxy resin. The polyimide has a structure of Formula 1 below:

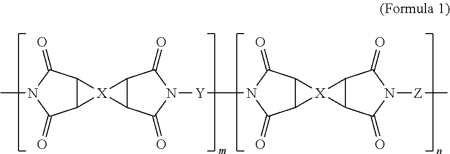

In Formula 1, m and n are each independently 1 to 600. X is a tetravalent organic group, a main chain of which contains an alicyclic compound group, preferably an alicyclic compound group having no benzene ring, including (but not limited to) the following groups or a combination thereof:

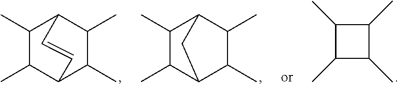

The polyimide of the present invention may further enhance the nature by excluding the benzene ring structure from the main chain of X.

Y is a divalent organic group, preferably containing (but not limited to) the following groups:

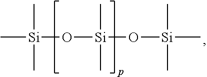

and p=0-20.

The chain length of Y is preferably short (p=0), and the longest chain length of Y may be p=20. If the chain length is too long, the nature of the polyimide will be destroyed.

Z is a divalent organic group, a side chain of which may contain a phenolic hydroxyl group or a carboxyl group. The content of the phenolic hydroxyl group or the carboxyl group approximately accounts for 5 to 30% of the number of moles of the polyimide. The development time may be controlled by adjusting the molar ratio of the side chain cover group, and when the content of the branched phenolic hydroxyl group or carboxyl group is high, the alkaline developer is preferred for the solubility and may improve the developability.

Z may include, but not be limited to, the following groups:

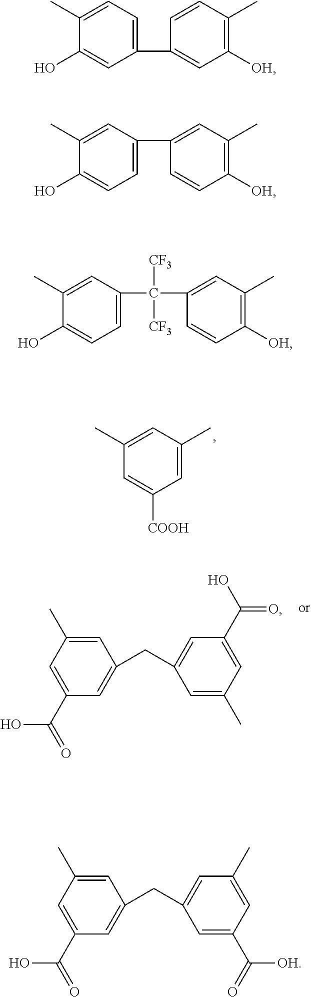

The main purpose of the thermal crosslinking agent is to cross-link with the PI backbone-OH group or the ortho position of the terminal-OH group via acid catalysis and heat treatment during hard baking after exposure so that the exposed and non-exposed areas have a difference in solubility, and then the pattern may be quickly formed. Generally, the amount of the thermal crosslinking agent is about 5-40% of the total weight of the transparent photosensitive resin. If the amount is less than 5%, the crosslinking will be insufficient and the resin won't be resistant to chemical solvents. If the amount exceeds 40%, the developability will be poor.

After exposure and absorption of a certain wavelength of light, the photo-crosslinking agent will produce free radicals to initiate or catalyze the polymerization of the corresponding monomers or prepolymers to form crosslinks. The UV/Visible absorption wavelength of the photo-crosslinking agent to be added in the present invention is between 300-450 nm, and if the exposure wavelength is outside the range, the exposure efficiency will be poor and thus will be prone to insufficient cross-linking. The addition amount of the photo-crosslinking agent is between 5 to 40% of the total weight of the transparent photosensitive resin. If it is less than 5%, the sensitivity is insufficient; and if it exceeds 40%, the developability is poor.

The synthesis steps of the polyimide were carried out by dissolving appropriate amount of the diamine monomer and the dianhydride monomer in N,N-Dimethylacetamide (DMAc), followed by reacting at 80° C. for 2 hours, followed by addition of toluene and heating to 140° C. for distillating. The diamine monomer containing the phenolic hydroxyl group or carboxyl group was further added, followed by reacting at 80° C. for 2 hours, followed by addition of toluene and heating to 140° C. for distillating, and followed by cooling after approximately four hours. The method for preparing the transparent photosensitive resin was carried out by adding the filler, the photo-crosslinking agent, and the thermal crosslinking agent into the polyimide colloid prepared above to obtain the transparent photosensitive resin of the present invention, (the photo-crosslinking agent and the thermal crosslinking agent may be added optionally.)

### Example 1

19.88 g (80 mmol) of 1,3-bis(3-aminopropyl)-1,1,3,3-tetramethyldisiloxane, 80.7 g of N,N-Dimethylacetamide (DMAc), 39.68 g (160 mmol) of bicyclo[2,2,2]oct-7-ene-2,3,5,6-tetracarboxylic dianhydride, and 21.14 g (80 mmol) of 2-(Methacryloyloxy)ethyl 3,5-diaminobenzoate were added into a 500 ml three-necked round bottom flask equipped with the mechanical stirrer and nitrogen inlet to form a solution. The solution was reacted at 50 to 80° C. for 4.5 hours. Afterwards, 45 g of toluene was added and the temperature was risen to 140° C. The mixture was kept stirring for 5.5 hours and then cooled to give a PIA-1 solution, 11.38 g of glycidyl methacrylate (GMA) was added into 50 g of the PIA-1 solution, which was then stirred at 70 to 100° C. for 24 hours to give the polyimide PSPI-1.

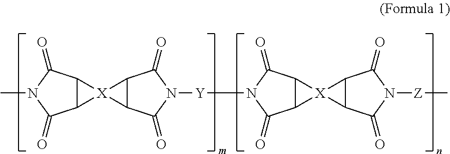

The structure of PSPI-1 is represented by Formula 1 above, wherein X is

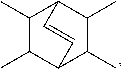

### Y is

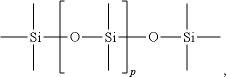

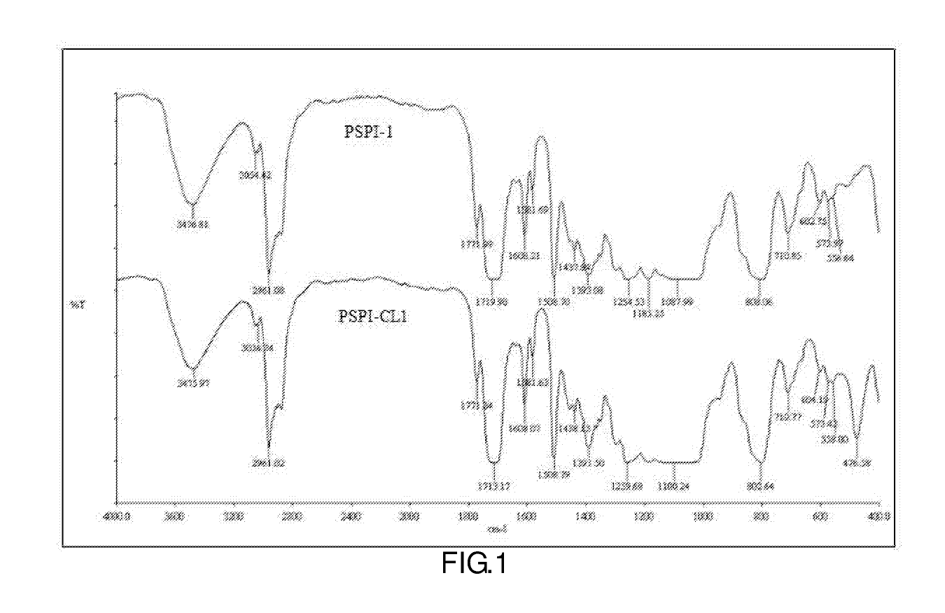

p=0, and Z is

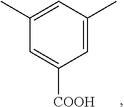

in which m=n=120. 5.55 g of the filler (10 nm silicon oxide) was added into 62.5 g of PSPI-1 and mixed uniformly to obtain the transparent photosensitive resin PSPI-CL1. The FTIR spectra of the polyimide PSPI-1 and the transparent photosensitive resin PSPI-CL1 were shown in FIG. 1. PSPI-CL1 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

From the FTIR spectra of the polyimide PSPI-1 and the transparent photosensitive resin PSPI-CL1 shown in FIG. 1, it can be seen that the transparent photosensitive resin PSPI-CL1 added with the filler, i.e. 10 nm silicon oxide, showed a characteristic absorption peak of O—Si—O at the wave number of 476 cm⁻¹ clearly.

### Example 2

13.40 g of the filler (10 nm silicon oxide) was added into 62.5 g of PSPI-1 solution from Example 1 and mixed uniformly to obtain the transparent photosensitive resin PSPI-CL2. PSPI-CL2 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 3

3.48 g of the filler (10 nm aluminum oxide) was added into 62.5 g of PSPI-1 solution from Example 1 and mixed uniformly to obtain the transparent photosensitive resin PSPI-CL3, PSPI-CL3 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Example 4

19.88 g (80 mmol) of 1,3-bis(3-aminopropyl)-1,1,3,3-tetramethyldisiloxane, 88.86 g of N,N-Dimethylacetamide (DMAc), 39.68 g (160 mmol) of bicyclo[2,2,2]oct-7-ene-2,3,5,6-tetracarboxylic dianhydride, and 29.30 g (80 mmol) of 2,2-bis(3-amino-4-hydroxyphenyl)hexafluoropropane were added into a 500 ml three-necked round bottom flask equipped with the mechanical stirrer and nitrogen inlet to form a solution. The solution was reacted at 50 to 80° C. for 4.5 hours. Afterwards, 45 g of toluene was added and the temperature was risen to 140° C. The mixture was kept stirring for 5.5 hours and then cooled to give a PIA-2 solution. 11.38 g of glycidyl methacrylate (GMA) was added into 50 g of the PIA-2 solution, which was then stirred at 70 to 100° C. for 24 hours to give the polyimide PSPI-2,

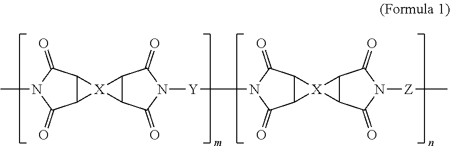

The structure of PSPI-2 is represented by Formula 1 above, wherein X is

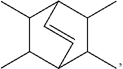

### Y is

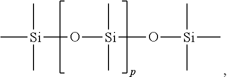

p=0, and Z is

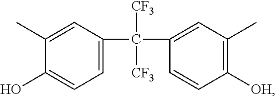

in which m=n=200. 13.40 g of the filler (10 nm silicon oxide) was added into 62.5 g of PSPI-2 and mixed uniformly to obtain the transparent photosensitive resin PSPI-CL4. PSPI-CL4 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1% (by weight) of sodium carbonate developer for 1 minute. After that, the hard baking procedure was carried out at 200° C. in a nitrogen oven for 2 hours to obtain a developed pattern with heat resistance.

### Example 5

19.88 g (80 mmol) of 1,3-bis(3-aminopropyl)-1,1,3,3-tetramethyldisiloxane, 98.78 g of N,N-Dimethylacetamide (DMAc), 31.38 g (160 mmol) of cyclobutane-1,2,3,4-tetracarboxylic dianhydride, and 29.30 g (80 mmol) of 2,2-bis(3-amino-4-hydroxyphenyl)hexafluoropropane were added into a 500 ml three-necked round bottom flask equipped with the mechanical stirrer and nitrogen inlet to form a solution. The solution was reacted at 50 to 80° C. for 4.5 hours. Afterwards, 45 g of toluene was added and the temperature was risen to 140° C. The mixture was kept stirring for 5.5 hours and then cooled to give a PIA-3 solution. 11.38 g of glycidyl methacrylate (GMA) was added into 50 g of the PIA-3 solution, which was then stirred at 70 to 100° C. for 24 hours to give the polyimide PSPI-3,

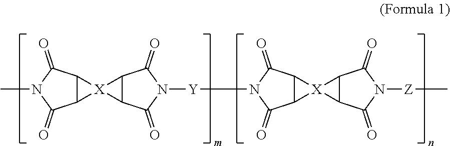

The structure of PSPI-3 is represented by Formula 1 above, wherein X is

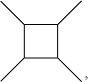

### Y is

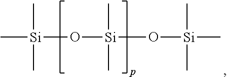

p=0, and Z is

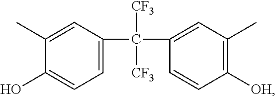

in which m=n=350. 13.40 g of the filler (10 nm silicon oxide) was added into 62.5 g of PSPI-3 and mixed uniformly to obtain the transparent photosensitive resin PSPI-CL5. PSPI-CL5 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 1

4.97 g (20 mmol) of 1,3-bis(3-aminopropyl)-1,1,3,3-tetramethyldisiloxane, 80.65 g of N,N-Dimethylacetamide (DMAc), 39.68 g (160 mmol) of bicyclo[2,2,2]oct-7-ene-2,3,5,6-tetracarboxylic dianhydride, and 36.00 g (140 mmol) of 2-(Methacryloyloxy)ethyl 3,5-diaminobenzoate were added into a 500 ml three-necked round bottom flask equipped with the mechanical stirrer and nitrogen inlet to form a solution. The solution was reacted at 50 to 80° C. for 4.5 hours. Afterwards, 45 g of toluene was added and the temperature was risen to 140° C. The mixture was kept stirring for 5.5 hours and then cooled to give a PIA-4 solution. 11.38 g of glycidyl methacrylate (GMA) was added into 50 g of the PIA-4 solution, which was then stirred at 70 to 100° C. for 24 hours to give the polyimide PSPI-4. 13.40 g of the filler (10 nm silicon oxide) was added into 62.5 g of PSPI-4 and mixed uniformly to obtain the transparent photosensitive resin PSPI-CL6. PSPI-CL6 was coated on the substrate by using a wire bar. After the pre-baking procedure at 90° C. in the oven for 8 minutes, a film having a film thickness of about 15 μm was obtained. The film was then exposed to energy of about 400 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

### Comparative Example 2

13.40 g of the filler (50 nm silicon oxide) was added into 62.5 g of PSPI-1 solution and mixed uniformly to obtain the transparent photosensitive resin PSPI-CL7 was coated on the substrate by using a wire bar. After the pre-baking procedure at 90° C. in the oven for 8 minutes, a film having a film thickness of about 15 μm was obtained. The film was then exposed to energy of about 100 mJ/cm² from the exposure machine (with a power of 7 kW) and then developed with 1 wt % (by weight) of sodium carbonate developer for 1 minute. After that, the hard baking procedure was carried out at 200° C. in a nitrogen oven for 2 hours to obtain a developed pattern with heat resistance.

The compositions and properties of the transparent photosensitive resins of Examples 1-5 and Comparative Examples 1-2 are shown in Table 1:

TABLE 1
Measurements and comparisons of the properties of the transparent
photosensitive resin

| | | | Percentage | | Chemical | | |
|---|---|---|---|---|---|---|---|
| | | | of phenolic | | resistance | | |
| | | | hydroxyl | | (soaking | | |
| Transparent | Percentage | Particle | group/carboxyl | | in 10% | | |
| photosensitive | of the filler | size of the | group | transmittance | NaOH for | yellowness | resolution |
| resin | (wt %) | filler (nm) | (mole %) | (@400-800 nm) | 30 mins) | value b* | (L/S) |
| Example 1 | 15 | 10 | 8.32 | 94% | No | 1.6 | 50 um |
| | | | | | thickness | | |
| | | | | | change | | |
| Example 2 | 30 | 10 | 8.32 | 98% | No | 1.1 | 50 um |
| | | | | | thickness | | |
| | | | | | change | | |
| Example 3 | 10 | 10 | 8.32 | 91% | No | 2.0 | 50 um |
| | | | | | thickness | | |
| | | | | | change | | |
| Example 4 | 30 | 10 | 12.8 | 95% | No | 1.8 | 50 um |
| | | | | | thickness | | |
| | | | | | change | | |
| Example 5 | 30 | 10 | 12.8 | 90% | No | 1.9 | 50 um |
| | | | | | thickness | | |
| | | | | | change | | |
| Comp. Ex. 1 | 30 | 10 | 14.57 | 82% | No | 3.0 | 75 um |
| | | | | | thickness | | |
| | | | | | change | | |
| Comp. Ex. 2 | 30 | 50 | 8.32 | 86% | No | 2.8 | 100 um |
| | | | | | thickness | | |
| | | | | | change | | |

In table 1, percentage of the filler refers to the percentage of the total weight of the filler in the total weight of the transparent photosensitive resin, and was calculated as the following formula:

Taking the transparent photosensitive resin PSPI-CL1 of Example 1 for example, it was formed by adding 5.55 g of the filler into 62.5 g of the polyimide PSPI-1 (having a solid content of 50%), and thus percentage of the filler (% filler) was equal to 15%.

Percentage of phenolic hydroxyl group/carboxyl group refers to the percentage (mole %) of phenolic hydroxyl group/carboxyl group of the divalent organic group Z of Formula 1 in the number of moles of the polyimide of Formula 1. Taking Example 1 for example, the original monomer of Z, i.e. 2-(Methacryloyloxy)ethyl 3,5-diaminobenzoate (having a molecular weight of 264.28), contains two carboxyl groups (having a molecular weight of 88) in each monomer and accounts for ¼ of the total number of moles of the polyimide, and therefore percentage of phenolic hydroxyl group/carboxyl group=

$$\frac{88}{264.28} \times 0.25 = 8.32 \% .$$

Taking Example 4 for example, the original monomer of Z, i.e. 2,2-bis(3-amino-4-hydroxyphenyl)hexafluoropropane (having a molecular weight of 366.26), contains two phenolic hydroxyl groups (having a molecular weight of 188) in each monomer and accounts for ¼ of the total number of moles of the polyimide, and therefore percentage of phenolic hydroxyl group/carboxyl group=

$$\frac{188}{366.26} \times 0.25 = 12.8 \% .$$

The transparent photosensitive resin compositions of Examples 1-3 of the present invention are formed by adding different weight percentage (wt %) of the fillers into the same polyimide, and all the resulting yellowness value (b* being measured by the color-difference meter with a value of greater than 2.0 indicating visually visible), transmittance, and resolution performance (the lower resolution being better) thereof are better than those of the traditional transparent photosensitive resin. In particular, the transparent photosensitive resin of Example 2 is preferred. As to Examples 4-5, both the transparent photosensitive resins (PSPI-CL4, PSPI-CL5) using different X and Z in the formulation can meet the requirements of low yellowness value and high transmittance. In contrast, the transparent photosensitive resin of Comparative Example 1 employed a different ratio of polyimide from that of the present invention, and its yellowness value, resolution and transmittance were poor. The transparent photosensitive resin of Comparative Example 2 used the filler having relatively large particle size, resulting in serious atomization phenomenon and poor transmittance.

What is claimed is:

1. A transparent photosensitive resin, comprising:
(a) a polyimide having a structure of Formula 1: 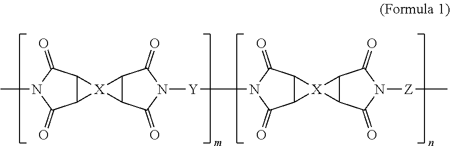
wherein m and n are each independently 1 to 600; X is a tetravalent organic group, a main chain of which contains an alicyclic compound group; Y is a divalent organic group, a main chain of which contains a siloxane group; Z is a divalent organic group, a side chain of which at least contains a phenolic hydroxyl group or a carboxyl group; and
(b) a filler including at least one of alumina, inorganic clay, mica powder, silicon oxide, aluminum oxide (Al₂O₃), zinc oxide, and zirconium oxide, the content of the filler accounting for 10-50% of the total weight of the transparent photosensitive resin; wherein the transparent photosensitive resin has a transmittance of greater than 90% at a wavelength of 400-700 nm and b value of chromatic aberration is less than 2.

2. The transparent photosensitive resin of claim 1, wherein the particle size of the filler is between 5 and 40 nm.

3. The transparent photosensitive resin of claim 1, further including an acrylic resin photo-crosslinking agent.

4. The transparent photosensitive resin of claim 1, further comprising a thermal crosslinking agent, which includes a phenolic compound, an alkoxy methylation amino resin, or an epoxy resin.

5. The transparent photosensitive resin of claim 1, wherein X is selected from the following functional groups and a combination thereof:

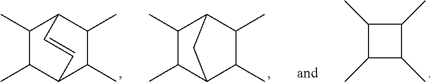

6. The transparent photosensitive resin of claim 1, wherein Y is selected from the following functional groups and a combination thereof: 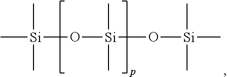
and wherein p=0-20.

7. The transparent photosensitive resin of claim 1, wherein Z is selected from the following functional groups and a combination thereof:

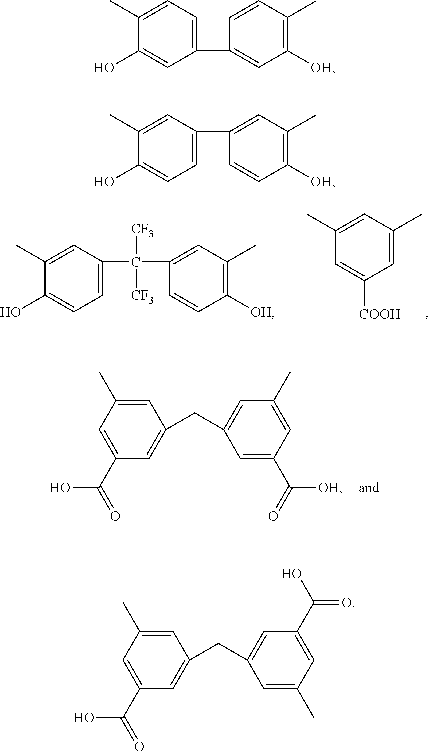

8. The transparent photosensitive resin of claim 1, wherein the phenolic hydroxyl group or the carboxyl group of Z in Formula 1 accounts for 5-30% of the number of moles of the polyimide.

9. The transparent photosensitive resin of claim 1, wherein X of Formula 1 doesn't contain a benzene ring.

10. The transparent photosensitive resin of claim 3, wherein the content of the acrylic resin photo-crosslinking agent accounts for 5-40% of the total weight of the transparent photosensitive resin.

11. The transparent photosensitive resin of claim 4, wherein the content of the thermal crosslinking agent accounts for 5-40% of the total weight of the transparent photosensitive resin.
